(19) United States
(12) Patent Application Publication
(10) Pub. No.: US 2020/0337146 A1
(43) Pub. Date: Oct. 22, 2020

(54) CIRCUIT BOARD STRUCTURE FOR HUMAN BODY INFRARED SENSOR TO REDUCE A FALSE ALARM RATE

(71) Applicant: BRICKCOM CORPORATION, Hsinchu Hsien (TW)

(72) Inventor: YUNG-HSIANG HUANG, HSINCHU HSIEN (TW)

(21) Appl. No.: 16/386,610

(22) Filed: Apr. 17, 2019

(51) Int. Cl. H05K 1/02; H05K 1/18; G01J 5/34; G01J 5/00

(52) U.S. Cl. CPC H05K 1/0201; H05K 1/18; G01J 5/34; H05K 2201/09063; H05K 2201/062; H05K 2201/10151; G01J 5/0025

(57) ABSTRACT

The present invention relates to a circuit board structure to which a human body infrared sensor is electrically connected. The circuit board structure comprises a circuit board and a heat insulation structure. The circuit board is provided with an electronic component disposing region, an isolation region and at least one conducting line. The conducting line stretches across the isolation region and the electronic component disposing region. The heat insulation structure is composed of at least one opening which surrounds the periphery of the isolation region. The human body infrared sensor is disposed in the isolation region and electrically connected to the at least one conducting line. Hereby, the change in temperature of the circuit board in the isolation region is moderated to avoid false operations of the human body infrared sensor caused by high temperature or temperature change. The human body infrared sensor is directly attached to the circuit board.

### FIELD OF THE INVENTION

The present invention relates to a circuit board structure, in particular to a circuit board structure for a human body infrared sensor to reduce a false alarm rate.

### BACKGROUND OF THE INVENTION

Referring to FIG. 1, a human body infrared sensor 1 (Pyro-electric Infrared Detector or Passive Infrared Detector) can detect the entry or exit of a person in the surrounding environment and is of a very important component for a smart home appliance. The smart home appliance can be activated while detecting the entry or exit of a person, which not only saves energy and electricity, but also effectively prolongs the service life of the smart home appliance, and is of a design that is quite friendly to the environment.

In the conventional way of setting the human body infrared sensor 1, the human body infrared sensor 1 is usually welded to a circuit board 3 by a high-leg wire 2. The human body infrared sensor 1 keeps away from the circuit board 3 in an overhead manner, because if the human body infrared sensor 1 is attached to the circuit board 3, the human body infrared sensor 1 is more likely to false operations when the product hardware design is less friendly to the human body infrared sensor 1, for example, an installation space of the circuit board 3 is narrow and there is an electronic component that is easy to generate heat. Also, at the beginning of the operation of an electronic system, or during the continuous operation period of the electronic system, the circuit board 3 may generate high temperature and rapid temperature changes. When the human body infrared sensor 1 is close to the circuit board 3, it is susceptible to false operations caused by high temperature or temperature changes. Therefore, it is necessary to use an overhead manner to prevent the human body infrared sensor 1 from contacting the circuit board 3, to solve the false operation problem caused by high temperature and temperature changes.

However, in order to elevate the human body infrared sensor 1, it is necessary to reserve a vertical space, resulting in space occupancy and difficulty in thinning. In addition, special processes and additional component preparation are required, thereby increasing component time and cost. In addition, the elevated human body infrared sensor 1 may be damaged or deflected by an external force once it is hit during the subsequent assembly, thereby reducing the yield of the product.

However, if the human body infrared sensor 1 is not elevated, another conventional solution is to down-regulate the sensitivity of the human body infrared sensor 1, which will cause the problem that the entry or exit of a person cannot be detected, instead. Apparently, the above-mentioned prior art cannot solve the existing problems and cannot meet the requirements on manufacturing and use.

### SUMMARY OF THE INVENTION

Therefore, the main objective of the present invention is to disclose a circuit board structure for a human body infrared sensor to reduce a false alarm rate, to meet the demand on manufacturing and use.

The present invention provides for a circuit board structure for a human body infrared sensor electrically connected thereto to reduce a false alarm rate. The circuit board structure comprises a circuit board and a heat insulation structure, wherein the circuit board is provided with an electronic component disposing region, an isolation region and at least one conducting line, and the at least one conducting line stretches across the isolation region and the electronic component disposing region.

The heat insulation structure is composed of at least one opening which penetrates through the circuit board and surrounds the periphery of the isolation region; the human body infrared sensor is disposed in the isolation region, and the human body infrared sensor is electrically connected to the at least one conducting line.

Therefore, according to the present invention, the human body infrared sensor is disposed on the isolation region of the circuit board, and can be directly attached to the circuit board, without being elevated. Then, by means of the heat insulation structure, even if the circuit board generates high temperature or undergoes temperature changes, the isolation region of the circuit board can also be prevented from being affected severely. Therefore, the false operations of the human body infrared sensor can be avoided. Thus, the human body infrared sensor of the present invention can be directly attached to the circuit board in the case of not reducing the sensitivity of the human body infrared sensor, which saves the space and reduces the possibility of damage or offset caused by external force impact, thereby improving the yield of the product.

### BRIEF DESCRIPTION OF THE DRAWINGS

FIG. 1 is a conventional structural diagram.

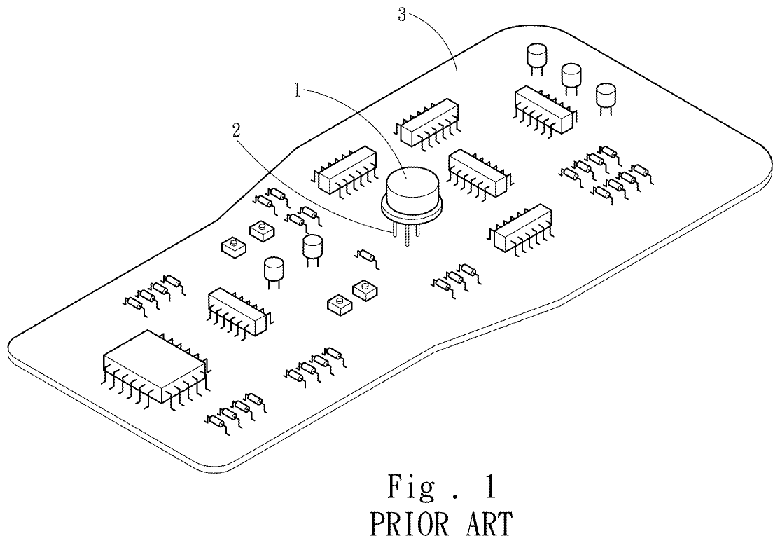

FIG. 2 is an exploded schematic diagram of a structure in which a human body infrared sensor of the present invention is mounted.

FIG. 3 is a combined schematic diagram of a structure in which the human body infrared sensor of the present invention is mounted.

### DETAILED DESCRIPTION OF THE PREFERRED EMBODIMENTS

For a further understanding and approval of the features, objective and functions of the present invention, the present invention is described according to a preferred embodiment and in conjunction with accompanying drawings.

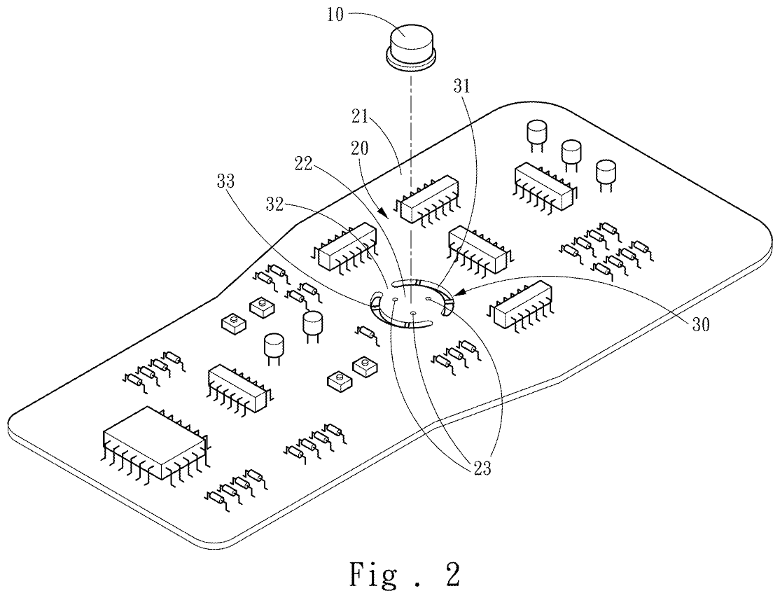

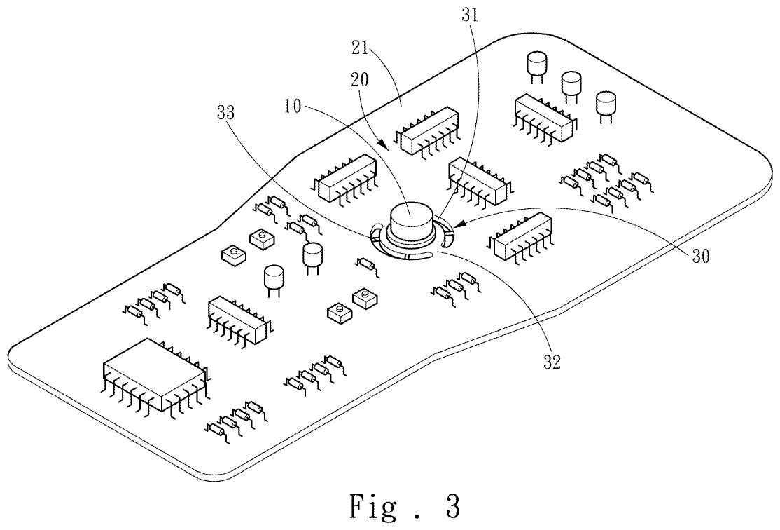

As shown in FIGS. 2 and 3, the present invention provides a circuit board structure for a human body infrared sensor 10 electrically connected thereto to reduce a false alarm rate. The circuit board structure comprises a circuit board 20 and a heat insulation structure 30, wherein the circuit board 20 is provided with an electronic component disposing region 21, an isolation region 22 and at least one conducting line 23. The at least one conducting line 23 stretches is disposed across the isolation region 22 and the electronic component disposing region 21 as well as exposed on the surface of the isolation region 22. In addition, the circuit board 20 may be a multi-layer board structure. The at least one conducting line 23 may be embedded in the multi-layer board structure of the circuit board 20, and functions as a connecting bridge for a voltage and a signal between an electronic component (not shown) of the electronic component disposing region 21 and the human body infrared sensor 10. Therefore, the electronic component may supply a voltage required by the human body infrared sensor 10 and receive a sensing signal from the human body infrared sensor 10.

As shown in FIG. 2, the heat insulation structure 30 is composed of at least one opening 31. The at least one opening 31 penetrates through the circuit board 20 and surrounds a periphery of the isolation region 22. The isolation region 22 is provided for disposal of the human body infrared sensor 10 which is electrically connected to the at least one conducting line 23. In actual implementation, the number of the openings 31 may be two, and two of the openings 31 are semicircular and are spaced apart by a gap 32. In addition, in order to increase the strength of the circuit board 20 and avoid the breakage of the isolation region 22, at least one reinforcing rib 33 may be respectively disposed on two of the openings 31. By disposal of the at least one reinforcing rib 33, the entire structure of the heat insulation structure 30 is further reinforced to avoid a risk of the breakage and damage of the circuit board 20. In addition, the number and the shape of the at least one opening 31 can be designed according to actual demands as long as the periphery of the isolation region 22 is surrounded, and the main function of the at least one opening 31 is to prevent a heat source from being transmitted to the isolation region 22, so as to avoid any false operations that the human body infrared sensor 10 disposed in the isolation region 22 is affected by high temperature or temperature changes, so as to reduce the false alarm rate of the human body infrared sensor 10 and meet the demand on use.

As described above, compared with the prior art, the present invention comprises the following advantages at least including:

1. By disposal of the isolation region and the heat insulation structure, the human body infrared sensor is able to be attached to the circuit board without reducing the sensitivity, thereby reducing the occupied space and lowering the manufacturing cost.

2. The human infrared sensor does not need to be elevated, which can reduce the risk of damage or displacement caused by external force impact, thereby increasing the yield.

3. By disposal of the reinforcing rib on the opening, the structural strength can be increased without affecting the effects of heat insulation and heat dissipation.

What is claimed is:

1. A circuit board structure for a human body infrared sensor electrically connected thereto to reduce a false alarm rate, comprising:
a circuit board, provided with an electronic component disposing region, an isolation region and at least one conducting line, wherein the at least one conducting line stretches is disposed across the isolation region and the electronic component disposing region; and
a heat insulation structure, composed of at least one opening, wherein the at least one opening penetrates through the circuit board and surrounds a periphery of the isolation region, wherein the isolation region is provided for disposal of the human body infrared sensor which is electrically connected to the at least one conducting line.

2. The circuit board structure for a human body infrared sensor to reduce a false alarm rate according to claim 1, wherein the number of the openings is two, and two of the openings are semicircular and are spaced apart by a gap.

3. The circuit board structure for a human body infrared sensor to reduce a false alarm rate according to claim 2, wherein at least one reinforcing rib is disposed on each of the openings.
